(19) United States
(12) Patent Application Publication
(10) Pub. No.: US 2026/0075883 A1
(43) Pub. Date: Mar. 12, 2026

(54) PREFERENTIALLY ORIENTED ELECTRODE FILM AND PREPARATION METHODS THEREOF

(71) Applicants: LoMaRe Chip Technology Changzhou Co., Ltd., Changzhou City (CN); LoMaRe Technologies Limited, London (GB)

(72) Inventors: Xudong Sun, Changzhou City (CN); Fengzhi Yu, Changzhou City (CN); Andrei Paul Mihai, London (GB); Bin Zou, London (GB); Jan Zemen, London (GB)

(21) Appl. No.: 18/827,153

(22) Filed: Sep. 6, 2024

(30) Foreign Application Priority Data
Jul. 7, 2023 (CN) 202310833485.1

(51) Int. Cl. H01L 29/49; C23C 14/02; C23C 14/06; C23C 14/35; H01L 21/28; H01L 29/51; H10B 61/00; H10N 30/87; H10N 50/80

(52) U.S. Cl. CPC H10D 30/6739; C23C 14/02; C23C 14/0641; C23C 14/35; H10D 64/01316; H10D 64/01318; H10D 64/0135; H10D 64/693; H10B 61/00; H10D 64/033; H10N 30/878; H10N 50/80

(57) ABSTRACT

The present invention provides a preferentially orientated electrode film and preparation methods thereof, relating to the technical field of thin film preparation, comprising a silicon-based substrate and a primary seed layer, a secondary seed layer and a bottom electrode layer grown sequentially on said substrate; said primary seed layer being an AₓB₁₋ₓN film or an A₃₋ₓB₁₋ₓN film, wherein A═Cu, Fe; B═Pd, Pt; O [symbol] x [symbol] 1; in which said secondary seed layer is made of one or more of the following films: chromium nitride film, titanium nitride film, tantalum nitride film, magnesium oxide film; and said bottom electrode layer is made of one or more of the following films: a platinum film, a titanium nitride film, a gold film, a strontium ruthenate film, or a niobium doped strontium titanate film, which has a preferential orientation in the (00/) crystallographic direction, to solve the problem that the existing films with (00/) preferential orientations are not obtainable on a Silicon based substrate.

### TECHNICAL FIELD

The present invention relates to the technical field of thin film preparation, and in particular relates to a preferentially oriented electrode film and preparation methods thereof.

### BACKGROUND TECHNOLOGY

A growing number of studies have shown that thin films with (00/) crystal-oriented structures (where/is generally an integer number in the range of 1 to 9) have a wide range of applications in microelectronics and nanoelectronics. Films with (00/) crystal orientation have better piezoelectric, ferroelectric, and magnetic storage properties compared to films with (111) crystal orientation preferential orientation and polycrystalline.

For example, in the field of magnetic random-access memories, epitaxial preparation of (00/) crystal oriented bottom electrodes results in an improvement of up to 50% or more in the tunneling magnetoresistance (TMR) value of the device compared to (11I) crystal oriented or mixed crystal oriented bottom electrodes. Again for example in the perovskite structure compounds, the (00/) preferentially oriented films also have better piezoelectric properties than the (111) preferentially oriented and polycrystalline films. However, most of the current research results are focused on substrates such as magnesium oxide and strontium titanate (STO), which are relatively well matched to the electrode lattice, and cannot be applied to the field of silicon-based semiconductors. Therefore, how to integrate (00/) crystal orientated thin films for the current silicon-based large-scale integrated circuit industry is a major issue.

### SUMMARY OF THE INVENTION

In order to overcome the above technical defects, an object of the present invention is to provide a preferentially oriented electrode film and preparation methods thereof, solving the problem that the existing silicon-based semiconductor field is not capable of obtaining (00I) preferentially oriented films on a substrate.

The present invention discloses a preferentially oriented electrode film, wherein
comprising a silicon-based substrate and a primary seed layer, a secondary seed layer and a bottom electrode layer grown sequentially on said substrate;
Said primary seed layer is an AₓB₁₋ₓN film, where A=Cu, Fe; B═Pd, Pt; 0<x<1, or preferably an A₃₋ₓB₁₋ₓN film, where A=Cu, Fe; B═Pd, Pt; 0<x<1, or more preferably an A₄₋ₓBₓN_{1-y} film, where A=Cu, Fe; B═Pd, Pt; 0≤x<4 and 0≤y<1 e.g., a Cu₃BN film, where B═Pd, Pt;
Said secondary seed layer is made of one or more of the following films: chromium nitride film, titanium nitride film, tantalum nitride film, magnesium oxide film;
Said bottom electrode layer is made of one or more of the following films: a platinum film, a titanium nitride film, a gold film, a strontium ruthenate film, or a niobium doped strontium titanate film having a preferential orientation in the (00/) crystallographic direction.

Preferably, said substrate comprises a silicon substrate, a surface oxidised silicon substrate, a surface nitridised silicon substrate, a silicon carbide substrate, a metal substrate, a glass substrate, a magnesium oxide substrate.

Preferably, the thickness of said primary seed layer and said secondary seed layer are both 2 nm to 500 nm.

Preferably, a buffer layer is provided between said substrate and said primary seed layer; said buffer layer is a metal film or a metal nitride film.

Preferably, said buffer layer comprises a tantalum film, a chromium film, a titanium film, a titanium nitride, a tantalum nitride film, and said buffer layer has a thickness of 2 nm to 50 nm.

The present invention also provides preparation methods of a preferentially oriented electrode film, comprising:
A substrate, and the said substrate is pre-treated and mounted on a sample holder in a magnetron sputtering apparatus;
Under a magnetron sputtering apparatus, a first target is connected and a first seed layer is grown under nitrogen and inert gas; wherein the primary seed layer formed is an AₓB₁₋ₓN thin film, where A=Cu, Fe; B═Pd, Pt; 0<x<1, or preferably an A₃₋ₓB₁₋ₓN film, where A=Cu, Fe; B═Pd, Pt; 0<x<1, or more preferably an A₄₋ₓBₓN_{1-y} film, where A=Cu, Fe; B═Pd, Pt; 0≤x<4 and 0≤y<1 e.g. a Cu₃BN film, where B═Pd, Pt;
Finishing the sputtering of the primary seed layer, a second target is connected and the secondary seed layer is grown under nitrogen/oxygen and inert gas; wherein the secondary seed layer formed is one or more of the following combinations of films: chromium nitride film, titanium nitride film, tantalum nitride film, magnesium oxide film;
The sputtering of the secondary seed layer is finished and a third target is connected to grow a bottom electrode layer having a preferential orientation in the (00/) crystallographic direction, wherein the bottom electrode layer formed is a combination of one or more of the following films: a platinum film, a titanium nitride film, a gold film, a strontium ruthenate film, or a niobium doped strontium titanate film.

Preferably, before said connection of the first target:
A fourth target is connected and a buffer layer is pre-grown on the substrate.

Preferably, the substrate temperature, the through gas flow rate and the pressure are determined based on the primary seed layer or the secondary seed layer formed.

Preferably, said primary seed layer and secondary seed layer formed have a thickness of 2 nm to 500 nm.

Preferably, said substrate comprises a silicon substrate, a surface oxidised silicon substrate, a surface nitridised silicon substrate, a silicon carbide substrate, a metal substrate, a glass substrate, a magnesium oxide substrate.

With the adoption of the above technical solutions, the following beneficial effects are achieved compared to the prior art:
The electrode film and its preparation method provided in the present application adopts AₓB₁₋ₓN film, which is easy to form (00/) crystallographic orientation, as the primary seed layer, and adopts chromium nitride, titanium nitride, tantalum nitride, magnesium oxide, etc, as the secondary seed layer, to obtain a highly preferentially oriented bottom electrode thin film structure in (00/) crystallographic orientation, which does not cause elemental diffusion even at high temperatures, and which not only can be used as a high-quality bottom electrode in semiconductor field to improve the performance of devices, but also can provide crystal orientation control for the subsequent growth of (00/) crystal oriented piezoelectric, ferroelectric, magnetic memory and other functional thin films.

### FIGURES

FIG. 1 shows a schematic structural diagram of Embodiment 1 of a preferentially oriented electrode film described in the present invention;

FIG. 2 shows a schematic diagram of a structure embodying a buffer layer in Embodiment 1 of a preferentially oriented electrode film described herein;

FIG. 3 shows a flowchart of Embodiment 2 of preparation methods of a preferentially oriented electrode film as described in the present invention;

FIG. 4 shows an XRD pattern of a film prepared in Embodiment 2 of preparation methods of a preferentially oriented electrode film as described herein;

FIG. 5 shows a transmission electron microscopy image of a film prepared in Embodiment 2 of preparation methods of a preferentially oriented electrode film described in the present invention.

### DETAILED EMBODIMENTS

The advantages of the present invention are further described below with accompanying figures and specific embodiments.

Exemplary embodiments will be described in detail herein, examples of which are represented in the accompanying figures. Where the following description refers to the accompanying figures, unless otherwise indicated, the same numbers in different accompanying drawings indicate the same or similar elements. The embodiments described in the following exemplary embodiments do not represent all embodiments consistent with the present disclosure. Rather, they are merely examples of devices and methods consistent with some aspects of the present disclosure as detailed in the appended claims.

The terms used in this disclosure are used solely for the purpose of describing particular embodiments and are not intended to limit the present disclosure. The singular forms of “a”, “said”, and “the” used in this disclosure and the appended claims are also intended to include the plural forms, unless the context clearly indicates otherwise. meanings. It should also be understood that the term “and/or” as used herein refers to and includes any or all of the possible combinations of one or more of the associated listed items.

It should be understood that while the terms first, second, third, etc. may be employed in the present disclosure to describe various pieces of information, such information should not be limited to these terms. These terms are only used to distinguish the same type of information from one another. Depending on the context, the word “if” as used here could be interpreted as “at . . . ” or “when . . . ” or “in response to a determination”.

In the description of the present invention, it is to be understood that the terms “longitudinal”, “lateral”, “upper”, “lower”, “front”, “back”, “left”, “right”, “vertical”, “horizontal”, “top”, “bottom”, “inside”, “outside” etc. indicating orientational or positional relationships based on those shown in the accompanying drawings, and are only to facilitate the description of the present invention and to simplify the description, and are not to indicate or imply that the device or element referred to must have a particular orientation, be constructed and operated with a particular orientation, and therefore are not to be construed as limitations of the present invention.

In the description of the present invention, unless otherwise specified and limited, it is to be noted that the terms “mounted”, “linked”, “connected” are to be understood in a broad sense, e.g., it can be a mechanical connection or an electrical connection, it can be a connection within two elements, it can be a direct connection or an indirect connection through an intermediate medium and the specific meaning of the above terms may be understood by a person of ordinary skill in the art in the light of the specific circumstances.

In the subsequent description, suffixes such as “module”, “part” or “unit” used to denote components are used only to facilitate the description of the present invention and have no specific meaning in themselves. Thus, “module” and “component” can be used interchangeably.

Embodiment 1: The present invention discloses a preferentially oriented electrode film for providing a bottom electrode film structure achieving (00/) highly preferential orientation on a silicon-based substrate, specifically, referring to FIG. 1, comprising a silicon-based substrate and a primary seed layer, a secondary seed layer, and a bottom electrode layer sequentially grown on said substrate; said primary seed layer is an AₓB₁₋ₓN film, wherein A=Cu, Fe; B═Pd, Pt; 0<x<1, or preferably an A₃₋ₓB₁₋ₓN film, where A=Cu, Fe; B═Pd, Pt; 0<x<1, or more preferably an A₄₋ₓBₓN_{1-y} film, where A=Cu, Fe; B═Pd, Pt; 0≤x<4 and 0≤y<1 e.g. a Cu₃BN film, where B═Pd, Pt; said secondary seed layer is made of one or more films including but not limited to the following: chromium nitride film, titanium nitride film, tantalum nitride film, magnesium oxide film; said bottom electrode layer using including but not limited to one or more of the following films: platinum film, titanium nitride film, gold film, strontium ruthenate (SrRuO₃) film or niobium doped strontium titanate (Nb-doped SrTiO₃) film having a preferential orientation in the (00/) crystal direction.

As an illustration, in the electrode film provided in the present embodiment, an AₓB₁₋ₓN film or preferably an A₃₋ₓB₁₋ₓN film which is prone to form (00/) crystal orientation is used as the primary seed layer, wherein A=Cu, Fe; B═Pd, Pt; and O (x<1; which ameliorates the problem of lattice mismatch that is prone to occur between a silicon-based substrate and the bottom electrode, and provides a template for the subsequent growth of the film in the (00/) crystalline orientation. And then the use of chromium nitride, titanium nitride, tantalum nitride, magnesium oxide, etc. as the secondary seed layer not only solves the problem of diffusion of copper elements (used in the primary seed layer) at high temperatures, but also has a crystal structure that is (00/) oriented, with a lattice constant that is much closer to that of platinum, titanium nitride and other bottom electrodes used in this embodiment, which further reduces the problem of the lattice mismatch between a silicon-based substrate and the bottom electrode layer, thereby growing a high quality (00/) crystal orientation bottom electrode film.

Based on the above, the highly preferential oriented bottom electrode film structure in the (00/) crystal direction in the present embodiment does not produce elemental diffusion even at high temperatures, and not only can be used as a high-quality bottom electrode in the semiconductor field to improve device performance, but also provides crystal direction control for the subsequent crystal growth of piezoelectric, ferroelectric, magnetic memory, and other functional thin films in the (00/) crystal direction, i.e., to obtain other films with highly preferential orientation.

In this embodiment, the above substrates include, but are not limited to, a silicon substrate, a surface oxidised silicon substrate, a surface nitridised silicon substrate, a silicon carbide substrate, a metal substrate, a glass substrate, or an existing substrate such as a magnesium oxide substrate, etc., and, as described above, the primary seed layer can be formed to readily have the (00/) crystalline orientation, and thus can overcome the problem of the existing (00/) highly preferentially oriented thin films are mainly applied to substrates such as magnesium oxide and strontium titanate (STO), etc., which are relatively matched to the bottom electrode lattice, but cannot be applied to the field of silicon-based semiconductors.

In the above embodiment, as a preference, the thicknesses of said primary seed layer and said secondary seed layer are both 2 nm to 500 nm. As a best preference, the thickness of the primary seed layer is 50 nm; the thickness of the secondary seed layer is 30 nm; the primary seed layer and the secondary seed layer have a certain thickness limit, so as to keep the crystal constants of the primary seed layer and the secondary seed layer consistent or similar, so as to make the subsequently grown bottom electrode film (or other films) have a (00I) highly optimised crystallographic orientation to grow high quality devices with film structures all of which are (00/) highly preferentially oriented, and crystallographic directions of the above mentioned primary seed layer and secondary seed layer are also (00/).

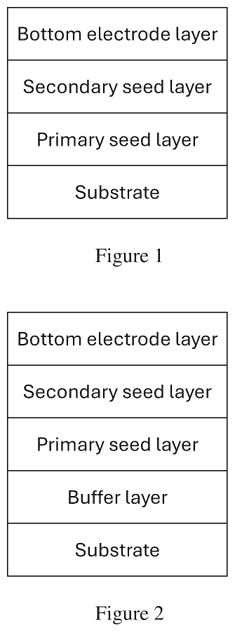

In this embodiment, optionally, referring to FIG. 2, a buffer layer may be provided between said substrate and said primary seed layer, which is provided to improve the surface roughness of the substrate as well as characteristics such as adhesion, specifically, said buffer layer includes, but is not limited to, a tantalum film, a tantalum nitride film, a chromium film, a titanium film, or a titanium nitride film, etc., and said buffer layer has a thickness of 2 nm to 50 nm, and the provided buffer layer can be pre-prepared before growing said primary seed layer, secondary seed layer and bottom electrode layer to increase the stability of connection between the subsequent primary seed layer and the substrate. It makes the subsequently grown primary seed layer, the secondary seed layer and the bottom electrode layer stably arranged on the substrate so as to enable the formation of the (00/) highly preferential crystal orientation to provide a crystal orientation control effect for the subsequent growth of functional films such as piezoelectric, ferroelectric and so on.

Embodiment 2: The present invention also provides a method of preparing a preferentially oriented electrode film for preparing the electrode film described in Embodiment 1 above that is highly preferential in the (00/) crystal direction, referring to FIG. 3, comprising:
S10: Providing a substrate, pre-treating said substrate, mounting it onto a sample holder in a magnetron sputtering apparatus;
In this embodiment, as described below, the primary seed layer, the secondary seed layer, and the bottom electrode layer are formed by sputtering, and said substrate comprises a silicon substrate, a surface oxidised silicon substrate, a surface nitridised silicon substrate, a silicon carbide substrate, a metal substrate, a glass substrate, a magnesium oxide substrate. The substrate may also include other existing substrates, as described in Embodiment 1 above. It is to be noted that the above pre-treatment is specifically a cleaning process of the substrate, including but not limited to RCA standard cleaning of the substrate surface, etc., and specifically applicable reagents may be used to clean the substrate surface, etc., according to the substrate material.

S20: Under a magnetron sputtering apparatus, a first target is connected and a primary seed layer is grown under nitrogen and inert gas; wherein the primary seed layer formed is an AₓB₁₋ₓN thin film, wherein A=Cu, Fe; B═Pd, Pt; 0<x<1, or preferably an A₃₋ₓB₁₋ₓN film, where A=Cu, Fe; B═Pd, Pt; 0<x<1, or more preferably an A₄₋ₓBₓN_{1-y} film, where A=Cu, Fe; B═Pd, Pt; 0≤x<4 and 0≤y<1 e.g. an Cu₃BN film, where B═Pd, Pt;

Specifically, before growing the primary seed layer by magnetron sputtering, the magnetron sputtering chamber is pumped to vacuum, specifically when the chamber vacuum is less than 7×10⁻⁸ m Torr (or adjusted according to the substrate or the sputtered primary seed layer), the substrate is loaded onto a sample holder in the magnetron sputtering equipment, and the first target may be an alloy target.

S30: Finish sputtering of the primary seed layer, connect a second target, and grow the secondary seed layer under nitrogen/oxygen and inert gas; wherein the secondary seed layer formed is a combination of one or more films including, but not limited to, a chromium nitride film, a titanium nitride film, a tantalum nitride film, and a magnesium oxide film; and the second target may be a metal target.

S40: The sputtering of the secondary seed layer is finished, and a third target is connected to grow a bottom electrode layer having a preferential orientation in the (00/) crystal direction, wherein the bottom electrode layer formed is a platinum thin film, a titanium nitride thin film, a gold thin film, a strontium ruthenate thin film, or a niobium doped strontium titanate thin film. The third target may also be a metal target.

In the preparation method provided in this embodiment, the primary seed layer, the secondary seed layer and the bottom electrode layer are sputtered on the substrate sequentially, the primary seed layer formed improves the lattice mismatch problem that tends to arise between the silicon-based substrate and the bottom electrode, and the secondary seed layer grown thereafter not only solves the problem of elemental diffusion at high temperatures (used for the primary seed layer), but also has the crystalline structure of the (00/) crystalline orientation. Further high quality (00/) crystal oriented bottom electrode films are grown, which all have the same or similar lattice constants, and the thickness of the said primary seed layer and the secondary seed layer formed is 2 nm to 500 nm, and as the best preference, the thickness of the primary seed layer is 50 nm; and the thickness of the secondary seed layer is 30 nm. Specifically, the growth time, temperature, and so on for sputtering growth of the primary seed layer, the secondary seed layer, and the bottom electrode layer described below are also different.

As a preferred embodiment, a buffer layer can be pre-grown on the substrate before connecting the first target: connecting the fourth target, said buffer layer being a metal film or a metal nitride film. Said buffer layer includes a tantalum film, a tantalum nitride film, a chromium film, a titanium film, or a titanium nitride film, and the thickness of said buffer layer is 2 nm to 50 nm, and the buffer layer can be pre-prepared prior to the growth of the primary seed layer, the secondary seed layer, and the bottom electrode layer mentioned above, in order to improve the surface roughness of the substrate as well as characteristics such as adhesion, and to increase the stability of connection between the subsequent primary seed layer and the substrate.

It is to be noted that in the above steps S10-S40, the substrate temperature, the gas flow rate and the pressure of the pass-through are determined according to the primary seed layer, the secondary seed layer and the bottom electrode layer formed, i.e., the sputtering conditions are controlled differently according to the different films of the first seed layer, the secondary seed layer and the bottom electrode layer formed. Specifically, as exemplary, based on the following specific embodiments, it is illustrated that the bottom electrode film prepared using the preparation method provided in this embodiment has a highly preferentially oriented (00/) crystalline orientation:

Provide a silicon (Si) substrate, which can be pre-treated by cleaning, etc.; pump the magnetron sputtering chamber to vacuum, and load the Si substrate onto the sample holder in the magnetron sputtering equipment; connect a CuₓPd₁₋ₓ (0<x<1) alloy target; pass nitrogen and oxygen gases, respectively, and turn on the DC sputtering power supply, and grow it at the power of 30 w to 80 w; finish the sputtering of the primary seed layer to obtain the primary seed layer of copper-palladium-nitride (CuₓPd₁₋ₓN, 0<x<1, or preferably Cu₃₋ₓPd₁₋ₓN, 0≤x<1 e.g. Cu₃PdN) film, the thickness of which is 50 nm; connected to the metal chromium target; respectively flow the nitrogen, argon gas, flow ratio of nitrogen-argon is 0.1 to 0.5, grow at the power of 20 w to 80 w; completion of the secondary seed layer sputtering, obtain the secondary seed layer of chromium nitride (CrN) film, the thickness of which is 30 nm; connect the metal platinum target; flow the pure oxygen gas, when the temperature rises to 100° C. to 300° C. then keep it there, turn on the DC sputtering power supply, grow at the power of 10 w to 50 w; turn off the sputtering power supply, the completion of the sputtering of platinum films, obtain the (00/) highly preferentially oriented film, the thickness of which is 40 nm; finish the film growth, take out the grown film.

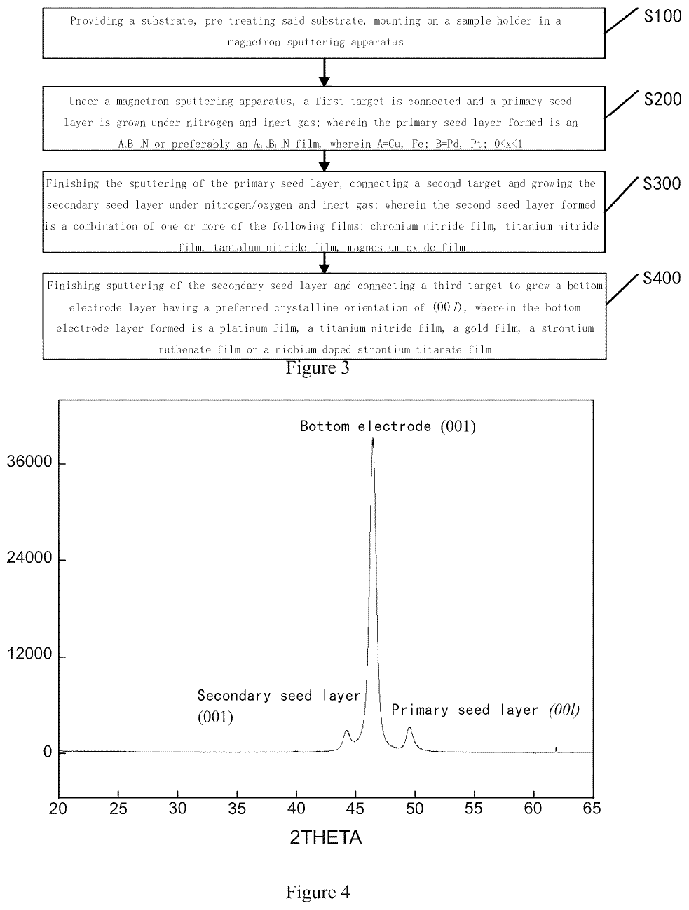

The films prepared in this embodiment were grown on a silicon substrate with a primary seed layer of copper-palladium-nitride (CuₓPd₁₋ₓN, 0<x<1, or preferably Cu₃₋ₓPd₁₋ₓN, 0≤x<1 e.g. Cu₃PdN) film, a secondary seed layer of chromium nitride (CrN) film, (00/) highly preferentially oriented bottom electrode platinum film, all of them with a high degree of (00/) crystallographic orientation, and at the same time, (00/) highly preferentially oriented bottom electrode layer platinum film can also be re-directed to grow subsequent films along the (00/) crystalline orientation. The XRD test pattern of the film grown in this embodiment is given in FIG. 4, where only the (00/) peak of the film is present and there is no (111) peak, which is a good indication that the prepared film of the bottom electrode has a highly preferentially oriented (00/) crystallographic orientation.

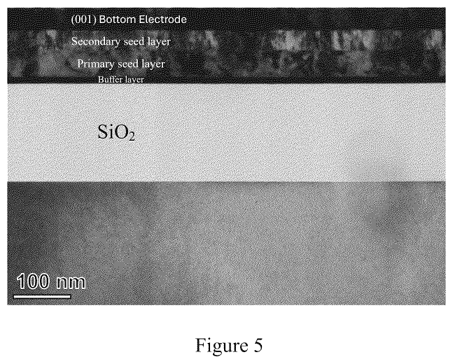

Based on the above exemplary preparation process, the thin films prepared in this embodiment may also be: a pre-grown tantalum film on the surface of silicon oxide (SiO₂), a primary seed layer of copper-palladium-nitride (CuₓPd₁₋ₓN, O<x<1, or preferably Cu₃₋ₓPd₁₋ₓN, 0≤x<1 e.g. Cu₃PdN) film, a secondary seed layer of chromium nitride (CrN) film, and a (00/) highly preferentially oriented bottom electrode platinum film, wherein all films have highly (00/) crystalline orientations, except for the tantalum film which is amorphous (i.e., the buffer layer described above), meanwhile the (00/) highly preferentially oriented bottom electrode layer of platinum film can also guide the growth of subsequent films along the (00/) crystalline orientation. The transmission electron microscopy (TEM) image of film grown at high temperature (450° C.) is given in FIG. 5, which shows that no elemental diffusion occurs between the layers of the film.

It should be noted that the embodiments of the present invention have better implementability, and are not a limitation of the present invention in any form, and any skilled person familiar with the field may use the above disclosed technical content to change or modify to the equivalent of the effective embodiments, as long as they are not deviate from the content of the technical solution of the present invention, any modifications or equivalent changes and modifications made to the above embodiments in accordance with the technical substance of the present invention, still fall in the scope of the technical solution of the present invention.

What is claimed is:

1. A preferentially oriented electrode film characterised by:
comprising a substrate and a primary seed layer, a secondary seed layer and a bottom electrode layer grown sequentially on said substrate;
said primary seed layer is an AₓB₁₋ₓN or A₃₋ₓB₁₋ₓN film, where A=Cu, Fe; B═Pd, Pt; 0<x<1;
said secondary seed layer is made of one or more of the following films: chromium nitride film, titanium nitride film, tantalum nitride film, magnesium oxide film;
said bottom electrode layer is made of one or more of the following films: a platinum film, a titanium nitride film, a gold film, a strontium ruthenate film, or a niobium doped strontium titanate film having a preferential orientation in the (00/) crystallographic direction.

2. An electrode film according to claim 1, characterised in that:
said substrate includes a silicon substrate, a surface oxidised silicon substrate, a surface nitridised silicon substrate, a silicon carbide substrate, a metal substrate, a glass substrate, and a magnesium oxide substrate.

3. The electrode film according to claim 1, characterised in that:
the thickness of both said primary seed layer and said secondary seed layer is 2 nm to 500 nm.

4. An electrode film according to claim 1, characterised in that:
a buffer layer is provided between said substrate and said primary seed layer, said buffer layer being a metal film or a metal nitride film.

5. An electrode film according to claim 4, characterised in that:
said buffer layer comprises a tantalum film, a chromium film, a titanium film a titanium nitride, or a tantalum nitride film, and the thickness of said buffer layer is 2 nm to 50 nm.

6. An electrode film according to claim 1, characterised in that:
the primary seed layer is an Cu₃BN film, where B═Pd, Pt.

7. A method of preparing a preferentially oriented electrode film, characterised in that it comprises:
a substrate, and the said substrate is pre-treated and mounted on a sample holder in a magnetron sputtering apparatus;
under a magnetron sputtering apparatus, a first target is connected, and a primary seed layer is grown under nitrogen and inert gas; wherein the primary seed layer formed is an AₓB₁₋ₓN or A₃₋ₓB₁₋ₓN film, wherein A=Cu, Fe; B═Pd, Pt; and 0<x<1;
finishing the sputtering of the primary seed layer, a second target is connected and the secondary seed layer is grown under nitrogen/oxygen and inert gas; wherein the secondary seed layer formed is a combination of one or more of the following films: chromium nitride film, titanium nitride film, tantalum nitride film, magnesium oxide film;
the sputtering of the secondary seed layer is finished and a third target is connected to grow a bottom electrode layer having a preferential orientation in the (00/) crystallographic direction, wherein the bottom electrode layer formed is a combination of one or more of the following films: a platinum film, a titanium nitride film, a gold film, a strontium ruthenate film, or a niobium doped strontium titanate film.

8. The method of preparation according to claim 7, characterised in that before connecting the first target as stated above:
a fourth target is connected and a buffer layer is pre-grown on the substrate, said buffer layer being a metal film or a metal nitride film.

9. A method of preparation according to claim 7, characterised in that:
the substrate temperature, the gas flow rate and the pressure of the gas passed through are determined based on the primary seed layer or the secondary seed layer formed.

10. A method of preparation according to claim 7, characterised in that:
the thickness of said primary seed layer and secondary seed layer formed is 2 nm to 500 nm.

11. A method of preparation according to claim 7, characterised in that:
said substrate includes a silicon substrate, a surface oxidised silicon substrate, a surface nitridised silicon substrate, a silicon carbide substrate, a metal substrate, a glass substrate, and a magnesium oxide substrate.

12. A method of preparation according to claim 7, characterised in that:
the primary seed layer is an Cu₃BN film, where B═Pd, Pt.
